(19) United States
(12) Patent Application Publication
(10) Pub. No.: US 2026/0322527 A1
(43) Pub. Date: Oct. 15, 2026

(54) SYSTEMS, APPARATUS, AND METHODS FOR REDUNDANCY VERSION OF LOW DENSITY PARITY CHECK CODE

(71) Applicant: Huawei Technologies Co., Ltd., Shenzhen (CN)

(72) Inventors: Van Hung Vu, Gatineau (CA); Yu Cao, Kanata (CA); Huazi Zhang, Zhejiang (CN); Haoyuan Wei, Stittsville (CA)

(21) Appl. No.: 19/452,720

(22) Filed: Jan. 19, 2026

Related U.S. Application Data
(63) Continuation of application No. PCT/CN2023/129070, filed on Nov. 1, 2023.
(60) Provisional application No. 63/514,883, filed on Jul. 21, 2023.

(51) Int. Cl. H04L 1/00

(52) U.S. Cl. CPC H04L 1/0041; H04L 1/0057

(57) ABSTRACT

Bits from a low density parity check (LDPC) coded bit sequence, obtained by encoding an input bit sequence, are transmitted in an initial transmission. In a further transmission, further bits from the coded bit sequence are transmitted. The further bits are bits from the coded bit sequence that were not included in the initial transmission. The further transmission is determined, by selection for example, from among a number of further transmissions that have associated self-decodability and combining gain properties. The determination of the further transmission from among the number of further transmissions is based on a traffic handling property that is related to the coded bit sequence.

### CROSS-REFERENCE TO RELATED APPLICATION

The present application is a continuation of International Patent Application PCT/CN2023/129070, entitled “Systems, Apparatus, and Methods for Redundancy Version of Low Density Parity Check Code,” filed on Nov. 1, 2023, and claims the benefit of U.S. Patent Application No. 63/514,883, entitled “System, Apparatus, and Method for Redundancy Version of LDPC Code,” filed on Jul. 21, 2023. The entire contents of these applications are hereby incorporated by reference.

### TECHNICAL FIELD

The present application relates to communications, and in particular to low density parity check (LDPC) coding and redundancy versions (RVs) for LDPC codes.

### BACKGROUND

In wireless communications, redundancy schemes such as Hybrid Automatic Repeat Request (HARQ) may be used to reduce or eliminate errors introduced by noise or interference in a communication channel. HARQ combines forward error correction with a retransmission scheme, which may define one or more different versions of an initial transmission. The different transmission versions are also known as redundancy versions (RVs).

It is desirable to improve the performance of redundancy versions according to various general and/or specific criteria.

Performance may be improved, for example, by providing for RV configurations that support high self-decodability and incremental redundancy (IR) combining gain.

### SUMMARY

Some aspects of the present disclosure relate to RVs with high self-decodable ability (“self-decodability”). Some aspects of the present disclosure relate to RVs with good IR combining gain. Some aspects of the present disclosure relate to RVs with both high self-decodability and good IR combining gain.

According to an aspect of the present disclosure, a method involves transmitting, in an initial transmission, bits from an LDPC coded bit sequence; and transmitting, in a further transmission, further bits from the LDPC coded bit sequence. The further transmission is determined, based on a traffic handling property related to the coded bit sequence, from among a number of further transmissions that have associated self-decodability and combining gain properties.

Another aspect of the present disclosure involves receiving and decoding a further transmission that includes further bits from an LDPC coded bit sequence. The further bits are further to bits from the LDPC coded bit sequence included in an initial transmission. The further transmission is determined from among a number of further transmissions, based on a traffic handling property related to the coded bit sequence. The number of further transmissions have associated self-decodability and combining gain properties.

An apparatus according to a further aspect of the present disclosure includes an encoder for encoding an input bit sequence by an LDPC code to obtain an LDPC coded bit sequence, and an interface, coupled to the encoder: for transmitting, in an initial transmission, bits from the LDPC coded bit sequence; and for transmitting, in a further transmission, further bits from the LDPC coded bit sequence. Based on a traffic handling property related to the coded bit sequence, the further transmission is determined, from among a number of further transmissions that have associated self-decodability and combining gain properties.

An apparatus may include an interface for receiving a further transmission that includes further bits from an LDPC coded bit sequence, and a decoder, coupled to the interface, for decoding the further transmission. The further bits are further to bits from the LDPC coded bit sequence included in an initial transmission, and the further transmission is determined, based on a traffic handling property related to the coded bit sequence, from among a number of further transmissions that have associated self-decodability and combining gain properties.

In other apparatus examples, an apparatus may include a processor configured to cause the apparatus to perform any of the methods as disclosed herein.

An apparatus may include a processor and a non-transitory computer readable storage medium that is coupled to the processor and stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

A system is also disclosed, and may include a first communication device and a second communication device. The first communication device may be configured to encode an input bit sequence by an LDPC code to obtain an LDPC coded bit sequence; to transmit, in an initial transmission, bits from the LDPC coded bit sequence; and to transmit, in a further transmission, further bits from the LDPC coded bit sequence. The second communication device may be configured to receive the further transmission, and to decode the further transmission. The further transmission is determined, based on a traffic handling property related to the coded bit sequence, from among a number of further transmissions that have associated self-decodability and combining gain properties.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 illustrates a circular buffer with starting positions for each RV in fifth generation (5G) new radio (NR) LDPC code.

FIG. 6 illustrates an example of self-decodable RVs.

FIG. 7 illustrates another example of self-decodable RVs.

FIG. 8 illustrates an example of self-decodable RV designs based on a circular buffer in NR.

FIG. 9 illustrates an example of forming an RV set from NR RVs and new RVs according to an embodiment.

FIG. 10 illustrates an example of RV subset selection based on a pre-emption indication, according to an embodiment.

FIG. 11 is a flow diagram illustrating more general example methods according to embodiments.

FIG. 12 is a block diagram illustrating an apparatus according to an embodiment.

### DETAILED DESCRIPTION

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

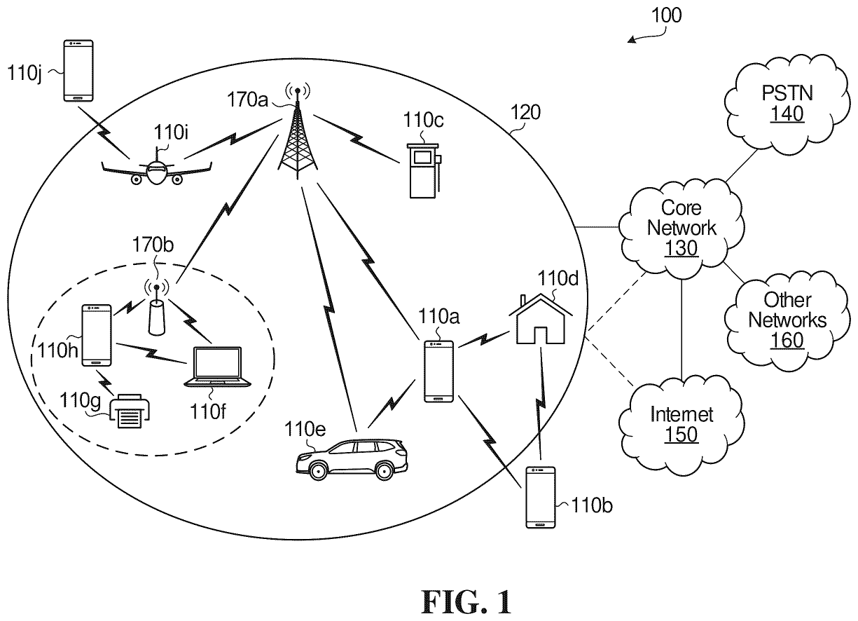

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

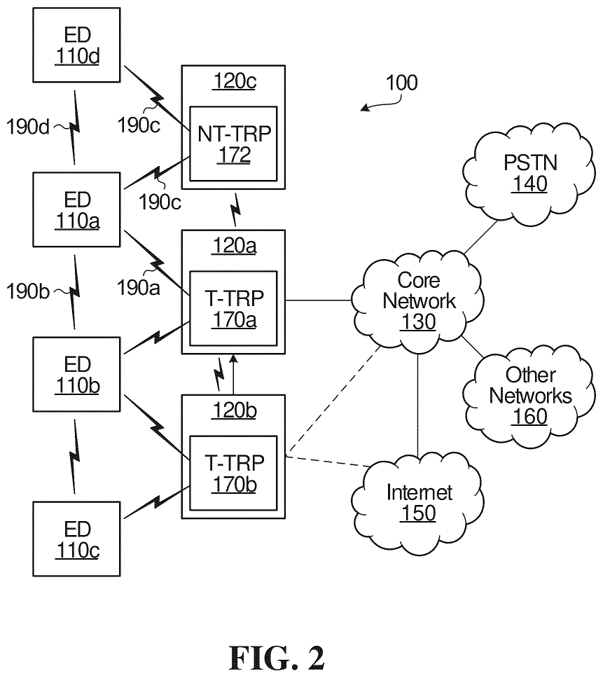

FIG. 2 illustrates an example communication system 100. In general, the communication system 100 enables multiple wireless or wired elements to communicate data and other content. The purpose of the communication system 100 may be to provide content, such as voice, data, video, signaling, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), Discrete Fourier Transform spread OFDMA (DFT-OFDMA) or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

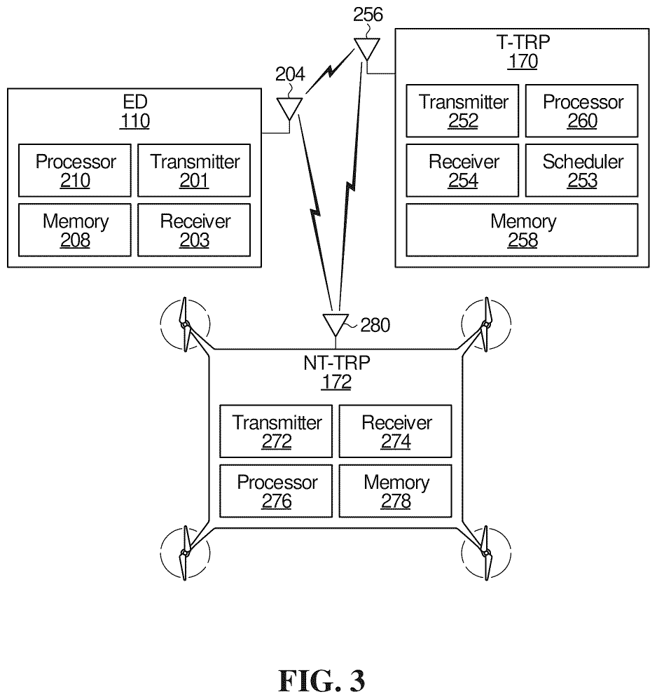

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IOT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices such as a watch, head mounted equipment, a pair of glasses, an industrial device, or apparatus (e.g., communication module, modem, or chip) in the forgoing devices, among other possibilities. Future generation EDs 110 may be referred to using other terms. Each base station 170a and 170b is a T-TRP and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., in the memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), a Central Processing Unit (CPU) or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form, such as high altitude platforms, satellite, high altitude platform as international mobile telecommunication base stations and unmanned aerial vehicles, which forms will be discussed hereinafter. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU, a CPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

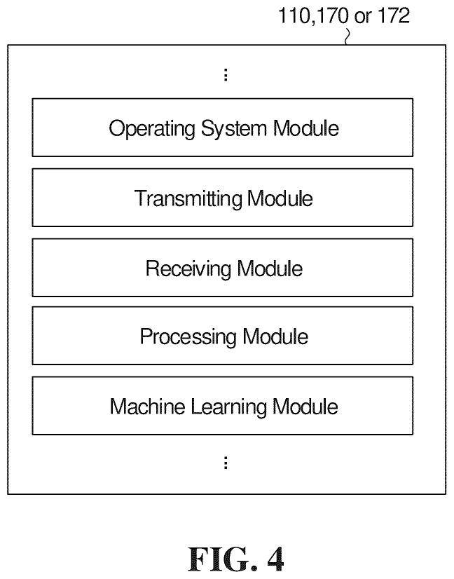

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or by a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU, a CPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

Having considered communications more generally above, attention will now turn to particular example embodiments.

In an example, a new RV set is disclosed, and has more RVs than an NR RV set. Additional RVs in the new RV set may have a good combination of IR combining gain and self-decodability. An RV set may include an existing NR RV set, such that the existing NR RV set may be the subset of the new RV set—in this case all NR RVs are included in the new RV set. The new RV set may also include completely new RV designs where some RVs have high self-decodability and low IR combining gain and vice versa. Other RVs may have low self-decodability and high IR combining gain. Some RVs may have a good combination of self-decodability and IR gain.

In an example, two subsets of RVs with different attributes can be generated from a larger RV set, such as the preceding RV set. A first subset (an IR RV subset for example) includes low self-decodability yet high IR combining gain at some RVs, and high self-decodability yet very low IR gain at other RVs. A second subset (an SD RV subset for example) includes good combination of IR combining gain and self-decodability (that is, high self-decodability at all RVs, and better IR gain than some RVs in the IR RV set).

“SD” refers to self-decodable.

In some embodiments, there may be more than two subsets of RVs with different attributes.

In an example, methods of RV configuration include methods to (automatically for example) select the RV subset by a UE, with minimal or no extra overhead in DCI, based on:
traffic priority;
QoS;
repetition configuration;
grant-free
autonomous retransmission in unlicensed band;
BS configuration;
pre-emption indication;
effective code rate in initial transmission.

“DCI” refers to downlink control information, “QoS” refers to quality of service, and “code rate” may be abbreviated to CR. “Grant-free” may also be referred to as configured grant.

An RV subset may be selected based on any one, or potentially more than one, of various conditions or parameters. The list provided above includes examples of such conditions or parameters.

In an example, methods of RV configuration include a one bit parameter (for example, a parameter known as “Redundancy version” in DCI, which may result in a total RV configuration size of 3 bits):
a 3^{rd} (last) bit can be used to indicate the RV subset,
using 3 bits to map to the RV index of the big RV set.

These three bits include a current two bit parameter in DCI, and an additional new one bit parameter. The new parameter may be used as a 3^{rd} (last) bit to indicate an RV subset, or the new parameter may be used in combination with the other two RV configuration bits in DCI, to use a total of 3 bits to map to an RV index in an RV set. These examples are also discussed in further detail herein.

In an LDPC code such as an NR LDPC code, a codeword before rate matching (the codeword may be referred to as a mother codeword) may consist of three disjoint portions or parts: systematic bits, core parity check bits and extended parity check bits. In an NR LDPC code, four different redundancy versions (RVs) including RV0, RV1, RV2 and RV3 are generated after rate matching. In an initial transmission, RV0 is normally selected in which most of the systematic bits are included in the set of coded bits. Among RV0, RV1, RV2, and RV3, since RV0 includes the most information bits, RV0 has the highest self-decodable ability (“self-decodability”) among all RVs. That is, RV0 can be self-decodable at highest code rate. In retransmission, the transmitter may select RV1, RV2 or RV3. Of these, only RV3 has high self-decodability, while RV1 and RV2 are not self-decodable at high code rate. The main reason for this disparity is that, at some code rates, RV1 and RV2 may consist of only parity check bits, resulting in a very low likelihood of successfully decoding the RV. However, each of RV1 and RV2 offers high IR combining gain with RV0 due to the inclusion of mostly parity bits in RV1 and RV2. In contrast, RV0 and RV3 have very low IR combining gain as they mostly include the information bits as systematic bits. In the NR LDPC RV scheme, an RV having high IR combining gain will have low self-decodability and vice versa.

In the example above, the transmitter may select RV1, RV2 or RV3 in retransmission. However, it is possible that RV0, RV1, RV2 or RV3 may be selected in retransmission. Therefore, RV0 can also be selected in retransmission, which is called HARQ with chase combining. Of RV0, RV1, RV2 and RV3, RV0 and RV3 have high self-decodability,

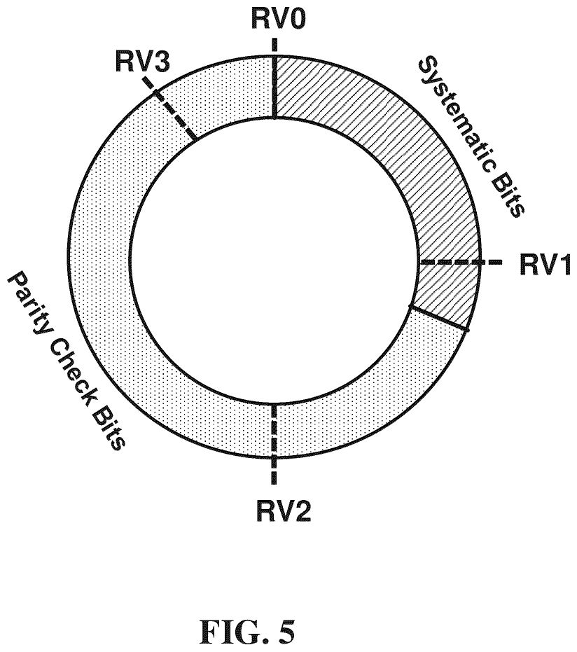

In the NR LDPC RV scheme, the bits of RV0, RV1, RV2 and RV3 are determined as follows. The coded bits in a mother codeword are first written into a circular buffer. The length of the circular buffer is identical to the number of coded bits in the mother codeword. As illustrated in FIG. 5, the beginning position of each RV is defined for each LDPC base-graph (BG). Given the number of coded bits in an RV or the length of RV, one starts to select the bits from the beginning position, wraps around following in a clock-wise direction, and restarts from the beginning of the buffer once it reaches the last bit in the buffer (accordingly, mother codeword). Here, RV0 would start from the first point in the circular buffer, and thus RV0 would include all systematic bits. RV3 starts from the end of circular buffer and it also includes most of the information bits. As a result, RV0 and RV3 have high self-decodability, yet offer low IR combining gain. In contrast, RV1 may only include a small portion of systematic bits, while RV2 may not include any systematic bits. It follows that RV1 and RV2 have low self-decodability, yet offer high IR combining gain.

The example above refers to “one” starting to select bits. This may also be referred to as bit selection starting to select bits from the beginning position. Bit selection may wrap around, following in a clock-wise direction and restarting from the beginning of the buffer. The restarting occurs once the last bit in the buffer, and accordingly that last bit in the mother codeword, is reached. Filler bits may be used, and if a filler bit is encountered then that filler bit is ignored in the bit selection process of an RV. With RV0 starting from the first point in the circular buffer, RV0 may include the highest number of systematic bits among all of the RVs. RV3 starts toward the end of circular buffer and it therefore includes mostly information bits (as systematic bits). This is why RV0 and RV3 have high self-decodability, but offer low IR combining gain. This is different from RV1, which may include a smaller portion of systematic bits, and RV2 might not include any systematic bits at all, resulting in the low self-decodability but high IR combining gain referenced above.

In the NR LDPC RV scheme, a BS can select either one of following RV sequences and indicate this selection via RRC signaling: [RV0, RV2, RV3, RV1], [RV0, RV0, RV0, RV0] and [RV0, RV3, RV0, RV3]. For each RV sequence, the transmissions of RVs can be then performed in the respective order. Among the three RV sequences, sequences [RV0, RV0, RV0, RV0] and [RV0, RV3, RV0, RV3] have high self-decodability, yet low IR combining gain. The BS can choose these sequences in some applications that require low-latency such as URLLC, such that, if a transmission is erased, the UE has a high chance to decode the data (information bits) in the next transmission. For sequence [RV0, RV2, RV3, RV1], RV2 has low self-decodability; thus, if RV0 is erased, the UE needs to wait to receive RV3, in order to decode the data, which results in increased transmission latency.

“RRC” refers to radio resource control. “URLLC” refers to ultra-reliable low latency communications.

In the sequence [RV0, RV0, RV0, RV0], the same coded bits are transmitted in each transmission, thus no IR combining gain can be obtained. The sequence [RV0, RV3, RV0, RV3] may have some IR combining gain. As shown in FIG. 5, however, most of the bits in RV0 and RV3 are identical, thus the IR combining gain between RV0 and RV3 may be low.

Some example RV implementations for LDPC codes aim to obtain a good combination of IR combining gain and self-decodability.

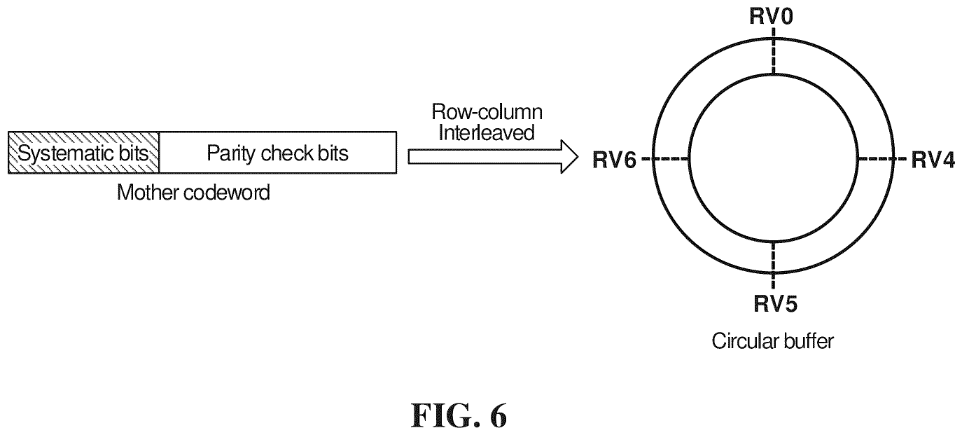

A first example, as shown in FIG. 6, keeps the same RV0 as in the NR LDPC code, and adds new self-decodable RVs, which are denoted as RV4, RV5 and RV6. The bits of the mother codeword are first interleaved by a row-column interleaver in order to evenly distribute the systematic bits among the parity check bits. The interleaved bits of the mother codeword are then written into a circular buffer. The starting position of each RV (RV0, RV4, RV5 and RV6) is evenly located in the circular buffer. It follows that RV4, RV5 or RV6 always includes a portion of systematic bits, allowing the RV scheme to improve its self-decodability, yet at the cost of reducing the IR combining gain compared to some NR LDPC RVs.

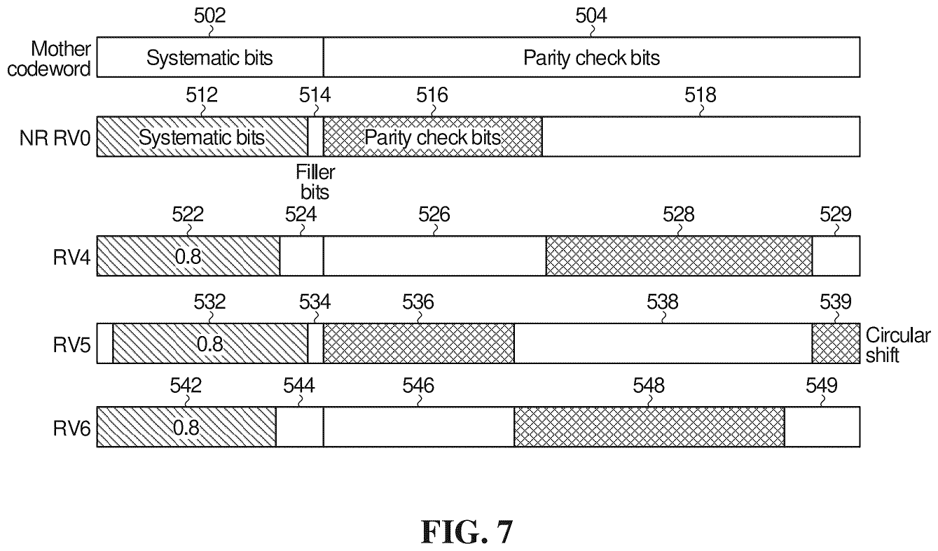

A second example, as shown in FIG. 7, adds new self-decodable RVs (denoted as RV4, RV5 and RV6) by selecting portions of systematic bits and parity check bits to be included in the new RVs. Such RV designs can improve the self-decodability as compared to RV1 and RV2 of the NR LDPC code, at the cost of reducing the IR combining gain as compared to RV2.

A mother codeword is shown at the top of FIG. 7, and includes systematic bits 502 and parity check bits 504. A mother codeword may also be referred to as a mother code.

In the example of FIG. 7, shaded parts represent the bits to be included in the RVs. RV4 and RV6 include the fraction 0.8 of systematic bits of NR RV0 that are located in the beginning-most positions. RV5 includes the fraction 0.8 of systematic bits of NR RV0 that are located in the ending-most positions.

The blank parts of the RVs in FIG. 7 represent bits that are not included in the RVs. The fraction of the systematic bits 512 of NR RV0 that are located in the beginning-most (first) positions in the bit sequence and are included in RV4 and RV6 are shown at 522, 542, respectively. Other systematic bits are not included in RV4 or RV6, as shown at 524, 544. The fraction of the systematic bits 512 of NR RV0 that are located in the ending-most (last) positions and are included in RV5 are shown at 532. Other systematic bits are not included in RV5, as shown at 534. Filler bits 514 represent padding, and are not included in the initial transmission NR RV0 or any of the other RVs.

The starting position of the parity check bits 516 of the initial transmission NR RV0 is a first position, such as the first position or beginning position of a circular buffer. 518 represents other mother codeword parity check bits that are not included in NR RV0, and are after the ending position of the NR RV0 parity check bits 516.

The starting position of parity check bits of each RV is the position right after the ending position of a previous RV.

With reference to FIG. 7, the starting position of the parity check bits 528 of RV4 is the position immediately following (which may also be referred to as right after) the ending position of the parity check bits 516 of the preceding RV (which may also be referred to as the previous RV), which is NR RV0. Other mother codeword parity check bits that are not included in RV4 are indicated at 526, 529. The bits 526 are before the starting position of the RV4 parity check bits 528, and are in effect skipped in selecting parity check bits 528 for RV4. The bits 529 are after the ending position of the RV4 parity check bits 528 and also are not selected for RV4.

In this example, the parity check bits of RV5 exceed the last bit of parity check bits of the mother code, thus they wrap around and restart from the beginning of the parity check bits of the mother code. In other words, the parity check bits of RV5 are circularly shifted once they reach the last bits of parity check bits of the mother code.

With reference again to FIG. 7, for RV5, the starting position of the parity check bits 539 is the position immediately following the ending position of the parity check bits 528 of the preceding RV, which is RV4. The parity check bits of RV5 exceed the last bit of parity check bits 504 of the mother codeword, and thus bit selection and the parity check bits for RV5 wrap around and restart from the beginning of the parity check bits 504 of the mother codeword. This may also be described as the parity check bits of RV5 being circularly shifted once they reach the last bits of the parity check bits 504 of the mother codeword.

Other mother codeword parity check bits that are not included in RV5 are indicated at 538. The bits 538 are before the starting position of the RV5 parity check bits 539, and are in effect skipped in selecting parity check bits 539 for RV5. The bits 538 are after the ending position of the RV5 parity check bits 536 and also are not selected for RV5.

Finally, in the example shown the starting position of the parity check bits 542 of RV6 is the position immediately following the ending position of the parity check bits 536 of the preceding RV, which is RV5. Other mother codeword parity check bits that are not included in RV6 are indicated at 546, 549. The bits 546 are before the starting position of the RV6 parity check bits 548, and are in effect skipped in selecting parity check bits 548 for RV6. The bits 549 are after the ending position of the RV6 parity check bits 548 and also are not selected for RV6.

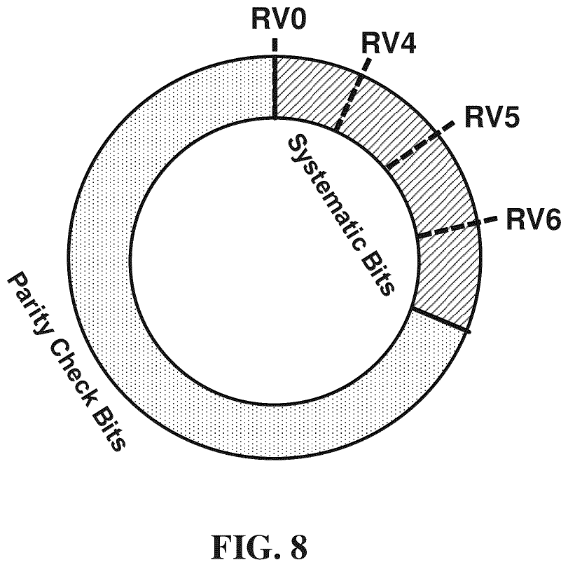

A third example, as shown in FIG. 8, generates new RVs (denoted RV4, RV5 and RV6) based on the circular buffer illustrated in FIG. 5, by simply choosing different starting position for each new RV. For example, FIG. 8 shows the starting positions for RV4, RV5 and RV6 in the circular buffer defined by an NR LDPC code. Here, the starting positions of the RVs are evenly located in the part of systematic bits of circular buffer. Because each RV always includes a portion of systematic bits, the RVs of this RV scheme can be self-decodable.

In yet another example, a new RV set may be created to better support both self-decodability and IR combining gain. The new RV set may include, for example, either or a combination of:
Additional RVs of RV4, RV5 and RV6 having a good combination of self-decodability and IR combining gain, may be included in the NR RV set to form a big RV set.
A completely new RV set, for example {RV0, RV1, . . . , RV6}, where some RVs may have low self-decodability but high IR gain and other RVs may have high self-decodability but low IR gain.

Examples of RV4, RV5, and RV6 are provided herein, including at least above.

From this big RV set, two subsets of RVs with different attributes can be generated:
An IR RV subset (for example, {RV0, RV1, RV2, RV3}): low self-decodability at some RVs (RV1 and RV2) but highest IR combining gain (RV2). Other RVs (RV0 and RV3 in this example) have high self-decodability yet very low IR combining gain. Note that, in the context of NR, IR RV subset simply refer to the NR RV set {RV0, RV1, RV2, RV3}.
An SD RV subset (for example, {RV0, RV4, RV5, RV6}): high self-decodability at all RVs and good IR combining gain at all RVs. RV4-RV6 should have better IR combining gain than RV1 and RV3 and comparable self-decodability to RV3.

This is one embodiment, in which two subsets of RVs are generated from a larger set of RVs. Other embodiments may involve generating two, or more than two, subsets of RVs from a larger set of RVs, by selecting RVs for each subset from the larger set for example.

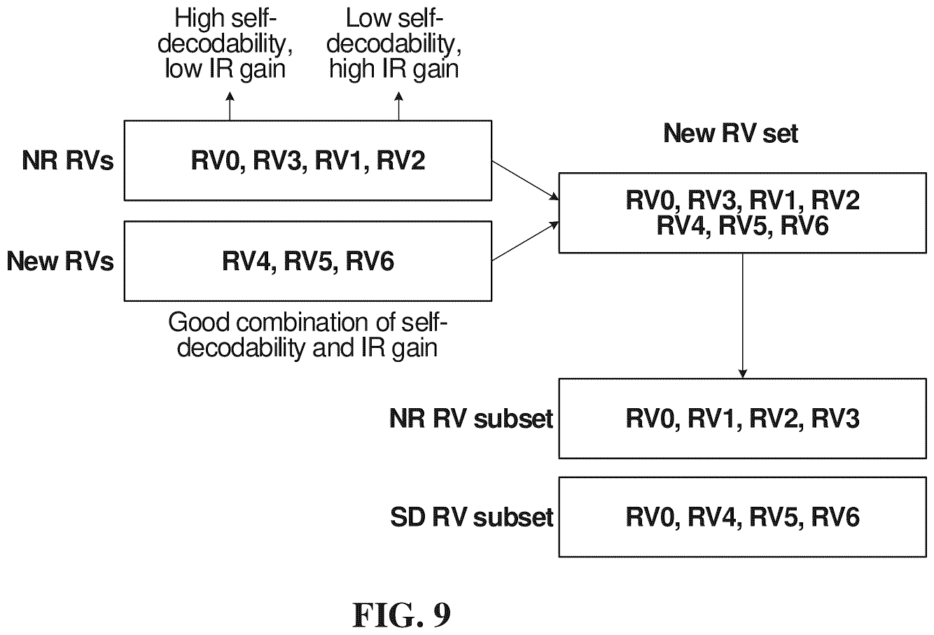

FIG. 9 illustrates an example of forming an RV set from NR RVs and new RVs according to an embodiment. The example in FIG. 9 is consistent with the example above, in which NR RVs {RV0, RV1, RV2, RV3} and new RVs {RV4, RV5, RV6} are combined into a larger RV set, and two RV subsets are selected or otherwise generated or formed from the larger RV set. The IR RV subset in the example above is shown in FIG. 9 as “NR RV subset,” and the SD RV subset is also shown in FIG. 9.

In yet another example, a new RV set may still consist of 4 RVs as in the NR LDPC RV scheme. However, some RVs may be replaced to provide a better combination of IR combining gain and self-decodability. For example, in FIG. 9, the new RV set may keep RV0 and RV2 as they offer best self-decodability and IR combining gain, respectively. Meanwhile, RV3 and/or RV1 in the NR LDPC RV scheme may be replaced by RV4 and/or RV5 if RV4 and RV5 can provide a comparable self-decodability to RV3, and higher IR combining gain compared to both RV3 and RV1. RV4 and/or RV5 may follow or be based on the RV designs previously illustrated in FIGS. 6 to 8, for example.

RVs may be selected from an RV set, or as a group by selecting an RV subset from among multiple RV subsets. As example is provided below.

Given the 2 subsets defined above and shown in FIG. 9, various methods may be used by a UE to select (or automatically select) the RV subset. Some methods may incur no extra overhead in the “Redundancy version” field (2 bits) of the Downlink Control Information (DCI) in 5G NR. Some selection methods may be based on: traffic priority; QoS; repetition configuration; grant-free; autonomous retransmission in unlicensed band; BS configuration; pre-emption indication; effective code rate (CR) of initial transmission.

This example refers to methods that may be used a UE. In some embodiments, RV selection is a network-side feature that is provided or supported by a network device, and a UE determines which RVs (which RV subset, for example) to use for retransmissions based on an RV configuration received from a network device. This example also refers to selecting or automatically selecting, but more generally RV subsets may be determined (or automatically determined) by selecting RVs or in some other manner.

Traffic priority and other items in this example, upon which some selection methods may be based, are also examples. More generally, some RV selection or determination methods may be based on one or more conditions or parameters, which are also referred to herein as traffic handling properties. For example, an RV, or more generally a further transmission, may be determined based on any one or more of the following: traffic priority; QoS; repetition configuration; grant-free; autonomous retransmission in unlicensed band; BS configuration; pre-emption indication; effective CR of initial transmission. Each of these examples is discussed in further detail herein, including at least below.

### Traffic Priority

In uplink (UL), when a UE has traffic(s) to transmit, the UE can send a scheduling request (SR) to BS if there is no resource already scheduled for the UE.

This example refers to a UE sending an SR to a BS. A BS is an example of a network device to which an SR may be sent by a UE.

The term “traffic(s)” refers to possible traffic of different types or categories, such as traffic associated with different services or, in the present example, traffic associated with different priorities.

In NR, an SR can include information of the traffic type through the SR resource configuration. Such SR resource configuration comprises a scheduling request ID associated with a logical channel in RRC, traffic priority and other information of such logical channel. In other words, the logical channel in RRC is configured with different priority of traffic, such as High Priority (for URLLC for example) and Low Priority (for eMBB). Based on the traffic priority, an RV subset with different self-decodability can be assigned.

Information of the traffic type in this example may also be referred to (or may include) an indication of the traffic type. In the above example of an SR resource configuration, scheduling request ID may refer to an SR identifier, and traffic priority may be specified or present in the form of an indication of traffic priority. The expression eMBB refers to enhanced mobile broadband. Assigning an RV subset refers to determining the RV subset that is to be used.

For example, the IR RV subset {RV0, RV1, RV2, RV3} can be automatically assigned for traffic with Low Priority (eMBB, for example). Meanwhile, the SD RV subset {RV0, RV4, RV5, RV6} can be automatically assigned for traffic with High Priority (URLLC, for example). High Priority traffic typically has a stringent requirement on latency, and retransmission is not preferred; thus the RV used in each transmission needs to have high self-decodability, in case a transmission suffers deep fading or is erased.

This example refers to a requirement on latency, but such a requirement may be referred to as a target and might not strictly be a requirement. Similarly, the RV used in each transmission strictly might not need to have high self-decodability, but preferably has high self-decodability. A transmission suffering deep fading or being erased are examples of conditions under which an RV that has high self-decodability may be preferred.

Alternatively, instead of automatically choosing by UE, another method is that the BS can use a 1-bit priority indicator in DCI to indicate the RV subset (IR RV subset or SD RV subset) to be used by the UE to transmit data based on the traffic priority.

These examples illustrate that automatically assigning an RV subset may involve selecting or choosing the RV subset by the UE for UL, or automatic selection by a network device (such as a BS) and transmitting signaling to the UE to indicate the selected RVs or RV subset so that the UE can determine which RVs to use. In the example above, the signaling is DCI to indicate traffic priority in a priority indicator. Other signaling and indication options related to traffic priority are possible. An RV or RV subset indicator may be determined by the network device based on traffic priority, for example, to indicate the RVs that are to be used by the UE.

### Quality of Service

In NR, different types of traffic or service may be associated with different quality of services (QoS). For example, as shown in Table 1 below [from Table 5.7.4.1 of 3GPP TS 23.501, Release 18, V18.1.0 (2023-03)], different 5G QoS Identifier (5QI) values correspond to respective different QoS, such as packet delay budget (latency requirement), priority level, packet error rate, and so on.

TABLE 1
Part of Table 5.7.4.1 of 3GPP TS 23.501, Release 18, V18.1.0
(2023-03), standardized 5QI to QoS characteristics mapping.
<23.501 - Table 5.7.4-1: Standardized 5QI to QoS characteristics mapping>

| | | | | | Default | | |
|---|---|---|---|---|---|---|---|
| | | | | | Maximum | | |
| | | | Packet | | Data | | |
| | | Default | Delay | Packet | Burst | Default | |
| 5QI | Resource | Priority | Budget | Error | Volume | Averaging | |
| Value | Type | Level | (NOTE 3) | Rate | (NOTE 2) | Window | Example Services |
| 1 | GBR | 20 | 100 ms | 10⁻² | N/A | 2000 ms | Conversational Voice |
| | (NOTE 1) | | (NOTE 11, | | | | |
| | | | NOTE 13) | | | | |
| 2 | | 40 | 150 ms | 10⁻³ | N/A | 2000 ms | Conversational Video |
| | | | (NOTE 11, | | | | (Live Streaming) |
| | | | NOTE 13) | | | | |
| 3 | | 30 | 50 ms | 10⁻³ | N/A | 2000 ms | Real Time Gaming, |
| | | | (NOTE 11, | | | | V2X messages (see |
| | | | NOTE 13) | | | | TS 23.287 [121]). |
| | | | | | | | Electrically distribution - |
| | | | | | | | medium voltage, |
| | | | | | | | Process automation |
| | | | | | | | monitoring |

Generally, for services having small packet delay budget an SD RV would be preferred to be used in each transmission, so that if a previous transmission is erased, the current transmission alone can still be decoded. It follows that an RV subset can be determined based on the QoS of corresponding traffic. For example, specific 5QI values in Table 1 related to low-latency applications can be mapped to the SD RV set and can be automatically selected by a UE. Thus, the SD RV subset {RV0, RV4, RV5, RV6} is automatically used by service with low packet delay budget, and the IR RV subset {RV0, RV1, RV2, RV3} is automatically used by service with high packet delay budget. Toward this end, a 5QI threshold can be defined in the standard such that if the 5QI value of a service or traffic exceeds that threshold, a UE will automatically select the SD RV subset. Otherwise, if the 5QI value of a service or traffic is smaller than that threshold, a UE will automatically select the IR RV subset.

This is one example of how the SD RV subset {RV0, RV4, RV5, RV6} may be automatically selected and used for traffic associated with a service that has a low packet delay budget, and the IR RV subset {RV0, RV1, RV2, RV3} can be automatically selected and used for traffic associated with a service that has a high packet delay budget. A 5QI threshold can be defined in a communications specification or standard such as the standard referenced above, for example, such that if the 5QI value of a service or traffic exceeds (as noted above, or meets, in some embodiments) that threshold, a UE (or network device) will automatically select the SD RV subset, or more generally RVs or an RV subset with relatively higher self-decodability. Otherwise, if the 5QI value of a service or traffic is smaller than or below that threshold in this example, a UE (or network device) will automatically select the IR RV subset, or more generally RVs or an RV subset with relatively lower self-decodability but higher IR combining gain.

### Repetition Configuration

In low-latency applications, repetition transmission may be used, in which data is transmitted repeatedly for several times in consecutive resources. The receiver can decode each transmission alone or combine multiple transmissions to improve decoding performance. As a result, the SD RV subset may be used for transmission with repetition since if some transmissions are erased, then the remaining transmission(s) can still be self-decoded. In 5G NR, physical uplink shared channel (PUSCH) with repetition is configured via the repK-RV field in RRC [Section 6.3.2 of 3GPP TS 38.331, Release 17, V17.4.0 (2023-03)]. Thus, if the field repK-RV is configured in RRC, a UE can also automatically select the SD RV subset. Otherwise, the IR RV subset can be used.

The above example indicates that the SD RV subset may be used for transmission with repetition or automatically selected if the field repK-RV is configured in RRC, but more generally RVs or an RV subset with relatively higher self-decodability may be preferred and used for transmission with repetition or automatically selected under this condition. Similarly, regarding the IR RV subset being used in the above example, more generally RVs or an RV subset with relatively lower self-decodability but higher IR combining gain, can be used.

PUSCH above refers to physical uplink shared channel.

### Grant-Free

In normal UL transmission, a UE would first need to request a scheduling resource through a scheduling request (SR) sent by the UE to BS. After obtaining the authorization from the BS via the DCI, the UE can start transmitting data in the scheduled resource. This procedure, however, increases the transmission latency for UL data transmission, and hence, is not suitable for applications with a tight latency budget.

To reduce the latency of UL data transmission, grant-free scheduling can be used. Different from above SR-based scheduling, grant-free scheduling enables a UE to transmit UL data based on self-scheduling in a resource preconfigured by a BS. More specifically, if a UE needs to transmit UL data, then the UE can directly transmit the data by using the preconfigured resource. In one example of RV set selection, if grant-free transmission is scheduled, then the UE can automatically select the SD RV subset. This is because in grant-free transmission, repetition usually is used to improve the reliability at the BS. As a result, having an SD RV in each transmission may be beneficial in that if some transmissions are erased, the remaining transmission(s) alone can be decoded.

In this example, features related to automatically selecting the SD RV subset may be applied more generally to automatically selecting RVs or an RV subset with relatively higher self-decodability. Otherwise, the IR RV subset, or more generally RVs or an RV subset with relatively lower self-decodability but higher IR combining gain, can be used.

### Autonomous Retransmission in Unlicensed Band

A UE operating in unlicensed band or spectrum may perform autonomous (that is, unscheduled by BS) UL transmission. The UE may sense that the channel is available (for example, via a listen-before-talk (LBT) procedure) and then perform an autonomous transmission and subsequent retransmission if an initial transmission has failed. For such autonomous (re) transmission in unlicensed band, RV index is indicated in the UCI. If the UE wants to keep 2 bits for RV index, the UE can automatically select the SD RV subset. Specifically, after the configured-grant retransmission timer expires, the UE can decide to use SD RVs {RV4, RV5, RV6} in the SD RV subset in retransmission since the initial transmission may be lost.

In this example, UCI refers to uplink control information. Features related to automatically selecting the SD RV subset may be applied more generally to automatically selecting RVs or an RV subset with relatively higher self-decodability. Otherwise, for example if the initial transmission is not lost, then the IR RV subset, or more generally RVs or an RV subset with relatively lower self-decodability but higher IR combining gain, can be used.

### BS Configuration

A BS can also configure which RV subset to be used, in RRC signaling. Supposing that either the IR RV subset {RV0, RV1, RV2, RV3} or the SD RV subset {RV0, RV4, RV5, RV6} is selected, the DCI will still have 2 bits to indicate RV index within the subset of 4 RVs, as in 5G NR. To indicate the RV subset, a new field, named “rvSet” for example, using 1 bit can be added to RRC to inform the UE about the RV subset. For example, rvSet=0 refers to the IR RV subset, and ruSet=1 refers to the SD RV subset.

In this example, features related to the SD RV subset may be applied more generally to RVs or an RV subset with relatively higher self-decodability. Similarly, features related to the IR RV subset may be applied more generally to RVs or an RV subset with relatively lower self-decodability but higher IR combining gain.

### Pre-Emption Indication

When eMBB data is transmitting, eMBB may use the IR RV subset by default, with transmission order or sequence [RV0, RV2, RV3, RV1] as in 5G NR. This is because eMBB does not have a stringent requirement on latency. Thus, if RV0 in a 1^{st} transmission is erased and RV2 in a 2^{nd} transmission cannot be self-decoded, a receiver can wait for RV3 in the 3^{rd} transmission.

In some cases, if URLLC data arrives, part of the time-frequency resource assigned for eMBB may be punctured for URLLC data. In other words, eMBB data is pre-empted by URLLC data. As a result, some CBs and respectively CBG(s) are erased in eMBB, and hence retransmission is needed. If this is the case, an SD RV should be used for retransmission of such erased CBs and corresponding CBG(s).

CBs refers to code blocks, and CBGs refers to code block groups. An SD RV, or other RVs or an RV subset with high self-decodability, may be preferred for retransmission in this example.

If other CBG(s) (in the same TB with the erased CBG) and the erased CBG can be retransmitted in one PDSCH, SD RV should be used since only one RV index is indicated in the DCI. If eMBB data is pre-empted by URLLC data (via pre-emption indication (PI) in the URLLC DCI), then the UE automatically knows that the retransmission of that eMBB data is based on the SD RV subset.

TB refers to transport block, and PDSCH refers to physical downlink shared channel. Again, an SD RV, or other RVs or an RV subset with high self-decodability, may be preferred in this example.

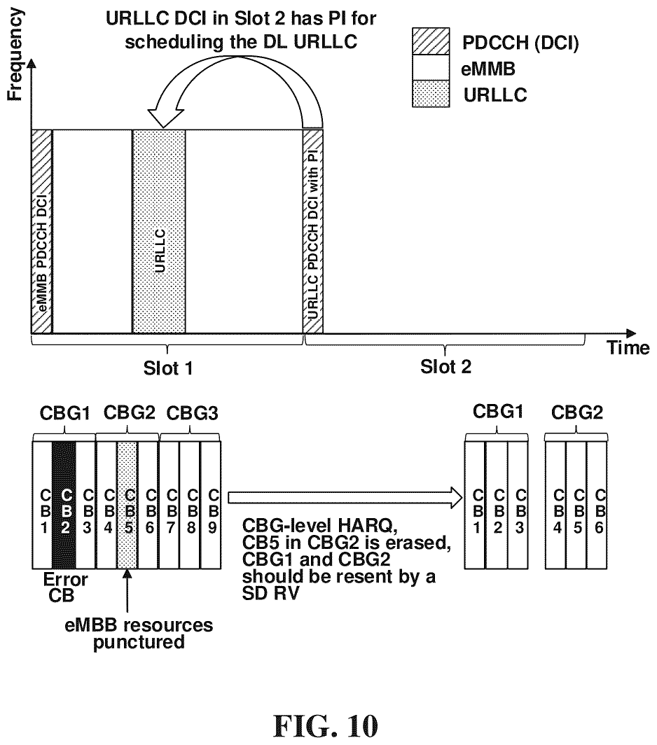

FIG. 10 provides an example of SD RV subset selection by a UE, based on a pre-emption indication. The example in FIG. 10 is an example of eMBB data being pre-empted by URLLC data. In this example, the eMBB data includes 3 CBGs, and each CBG has 3 CBs. The time-frequency resource of CB5 is pre-empted by URLLC data, so CB5 is erased at the UE. Further, CB2 is in error at the UE (that is, not successfully decoded). It follows that retransmission of CB2 and CB5 is required. If CBG-level HARQ is used, BS would retransmit CBG1 and CBG2. Here, the UE receives the PI in the DCI via URLLC PDCCH, so the UE knows that CB5 is pre-empted. As a result, the UE may automatically assume that the BS will select the SD RV subset for retransmission.

In this example, PDCCH refers to physical downlink control channel (PDCCH). The 3 CBGs are labelled (CBG1, CBG2, CBG3 at the bottom left), and the 9 CBs (each CBG has 3 CBs, for a total of 9 CBs) are labelled CB1 through CB9. Regarding automatic selection of the SD RV subset in this example, more generally RVs or an RV subset with high self-decodability may be selected for retransmission, because eMBB CB5 was not transmitted and therefore self-decodable RVs may be preferred in this scenario.

The above example also refers to a pre-emption indication in the form of the PI in DCI. However, in other embodiments pre-emption may impact a UL transmission, and accordingly an indication may be transmitted by a UE to a network device, in DCI for example.

### Effective Code Rate of Initial Transmission

From the circular buffer illustrated in FIG. 5 for NR LDPC codes, if the effective code rate (CR) of an initial transmission is low, RV0 would include many parity bits. It follows that, for RV transmission order [RV0, RV2, RV3, RV1] in 5G NR, IR combining gain obtained by RV2 together with RV0 is reduced with decreasing effective CR in initial transmission, especially for LDPC BG1 in which the mother CR is ⅓. This is because reducing the effective CR yields an increasing number of coded bits overlapping between RV0 and RV2, thus decreasing the IR combining gain. To achieve both good IR combining gain and self-decodability, the SD RV subset {RV0, RV4, RV5, RV6} can be automatically selected by the UE for low CRs. For example, for each LDPC BG, a CR threshold R can be defined in a standard such that if the effective CR of initial transmission is smaller than R, the UE can automatically select SD RV subset {RV0, RV4, RV5, RV6}. Otherwise, if the effective CR of an initial transmission is larger than R, the UE can select the IR RV subset {R0, RV1, RV2, RV3}. Note that, in the context of NR, the IR RV subset refers to the NR RV set {R0, RV1, RV2, RV3}.

For low effective CR, a method to generate an SD RV subset can be based on SD RV designs, such as those shown in the example FIGS. 6-8. Alternatively, a method to generate an SD RV subset can be based on NR RV designs, such as the RV subset {RV0, RV3, RV0, RV3}, where RV0 and RV3 are determined by NR LDPC codes.

As in other examples, features related to SD RVs may be applied more generally to RVs or an RV subset with high self-decodability. Features related to IR RVs may be applied more generally to RVs or an RV subset with lower self-decodability and higher IR combining gain.

Many of the foregoing examples refer to UE determination of RVs or RV subsets. RV or RV subset selection may also or instead be implemented or supported at a network side, by a network device such as a BS for example.

Given the two RV subsets defined above, BS may also perform RV configuration (RV selection and indication) via DCI signaling. Specifically, if the size of the “Redundancy version” parameter in the DCI of PDCCH can be increased, 1 extra bit can be added to the current 2 bits of RV configuration (total 3 bits) for the BS to indicate which RV subset shall be used. Two example methods for using such 3 bits to determine RV index are as follows:
RV set is selected based on the 3^{rd} bit of “Redundancy version” parameter in the DCI. For example, if the 3^{rd} bit is 0 (for eMBB traffic for example), then the IR RV subset {RV0, RV1, RV2, RV3} can be selected. Otherwise, if the 3^{rd} bit is 1 (for URLLC traffic for example), then the SD RV subset is selected. Further, the mapping from bits to RV index is also based on the first 2 bits. For example, bits 00, 01, 10 and 11 may correspond to RV0, RV4, RV5 and RV6, respectively.
In another example, the big RV set {RV0, RV1, . . . , RV6} can use 3 bits to map to the RV index. For example, bits 000, 001, 010, 011, 100, 101 and 110 may correspond to RV0, RV1, RV2, RV3, RV4, RV5 and RV6, respectively.

### Overview

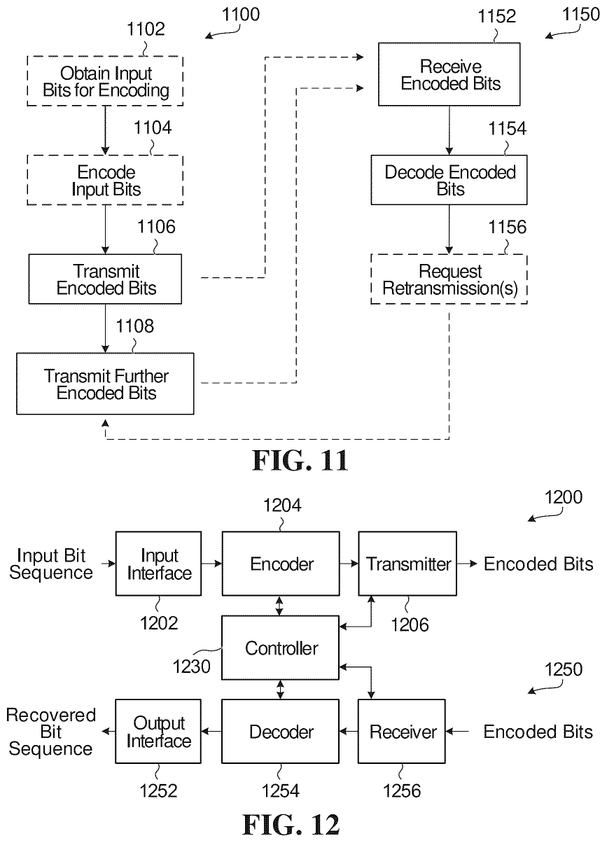

Various aspects of the present disclosure are described herein and shown in the drawings by way of example. FIG. 11 is a flow diagram illustrating more general example methods according to embodiments. At the left, 1100 in FIG. 11 illustrates operations or features that may be provided or supported at an encoder or transmitter-side device, and at the right, 1150 illustrates operations or features that may be provided or supported at a decoder or receiver-side device. For ease of reference, in the following description of FIG. 11, a device at which encoding and/or transmitting features may be implemented or supported is called a first communication device, and a device at which decoding and/or receiving features may be implemented or supported is called a second communication device. Embodiments may involve either or both of such devices.

With reference first to 1100, from a transmitting device perspective the transmitting at 1106 is intended to represent transmitting bits from an LDPC coded bit sequence in an initial transmission. The transmitting at 1108 represents transmitting further bits from the LDPC coded bit sequence in a further transmission. These further bits are encoded bits that are further to the encoded bits transmitted at 1106, and are referenced as further encoded bits at 1108. Such further bits may also be referred to as additional bits or redundant bits, or by some other name. An initial transmission at 1106 and a further transmission at 1108 may include some of the same bits from the LDPC coded bit sequence, but at least some bits in the further transmission at 1108 are further encoded bits from the LDPC coded bit sequence that are not included in the initial transmission at 1106. For example, a further transmission at 1108 may include one or more systematic bits that are not included in the initial transmission at 1106, one or more parity check bits that are not included in the initial transmission at 1106, or both one or more systematic bits and one or more parity check bits that are not included in the initial transmission at 1106.

An RV related to the initial transmission is an example of a further transmission at 1108. With reference to FIG. 5, for example, each of RV1, RV2, and RV3 includes further bits from a coded bit sequence that are not included in the initial transmission RV0. FIG. 8 illustrates another example in which each of RV1, RV2, and RV3 includes further bits from a coded bit sequence that are not included in the initial transmission RV0. A further example is illustrated in FIG. 7, in which each of RV4, RV5, and RV6 includes further bits from a coded bit sequence that are not included in the initial transmission RV0.

There may be one, or more than one, further transmission after an initial transmission, and RV subsets as disclosed herein are examples of embodiments in which there may be multiple further transmissions after an initial transmission, with each further transmission including further bits that from an LDPC coded bit sequence that are not included in the initial transmission, and/or in one or more preceding or previous further transmission(s).

A further transmission at 1108 may have been determined, from among a number of further transmissions that have associated self-decodability and combining gain properties. In this context, examples of “determined” include selected (by a network device such as a BS), or auto-assigned or auto-selected (by a terminal device such as a UE). These examples are also explained in further detail elsewhere herein.

Regarding a number of further transmissions from which a further transmission is determined, an RV may be determined from RVs in an RV subset in some embodiments. It should be appreciated, however, that not all embodiments necessarily involve RV subsets. Individual RVs may be determined for a next transmission from a full set of RVs (from the new RV set in FIG. 9, for example), without dividing, grouping, or otherwise separating the RVs into subsets. Embodiments disclosed herein include embodiments in which 3 bits are used to map to an RV index of the big RV set, and this is an example of how a further transmission (an RV in this example) may be determined without using RV subsets.

The further transmission at 1108 is determined based on a traffic handling property that is related to the coded bit sequence. The following are examples of a traffic handling property based upon which a further transmission may be determined: traffic priority; QoS; repetition configuration; grant-free; autonomous retransmission in unlicensed band; BS configuration; pre-emption (including an indication in some embodiments; effective CR of the initial transmission.

In some embodiments, the traffic handling property based upon which a further transmission is determined is a traffic priority associated with the LDPC coded bit sequence. In an uplink example, a device such as a UE that has traffic to transmit may send an SR to a network device such as a BS if there is no resource already scheduled for the UE, and the further transmission is determined (assigned by the BS or automatically selected by the UE, for example) based on the traffic priority. An indication of the traffic type and/or an indication of traffic priority may be transmitted by the device that has traffic to send (and received by the network device), and the further transmission may then be determined by the network device based on the traffic type or traffic priority.

As an example, the NR RV subset {RV0, RV1, RV2, RV3} in FIG. 9 can be automatically assigned for traffic with Low Priority, and the SD RV subset {RV0, RV4, RV5, RV6} in FIG. 9 can be automatically assigned for traffic with High Priority. The RVs other than RV0 in these subsets are examples of further transmissions with associated self-decodability and combining gain properties. Self-decodability is lower in the NR RV subset and higher in the SD RV subset, and combining gain (in particular IR coding gain) is higher in the NR RV subset and lower in the SD RV subset).

In the case of network device determination of the further transmission such as an RV, the network device may transmit (and the UE may receive) an indication of the determined further transmission, such as a 1-bit priority indicator in DCI to indicate the RV subset to be used by the UE to transmit data based on the traffic priority.

More generally, determining a further transmission by a UE may involve selecting the further transmission (by selecting an RV or an RV subset for example) by the UE for UL. Other embodiments may involve selecting by a network device and transmitting signaling to the UE to indicate the selected further transmission, so that the UE can receive the signaling and determine the further transmission to use based on the received signaling. In the example above, the signaling is DCI to indicate traffic priority in a priority indicator. Other signaling and indication options related to traffic priority are possible, and an illustrative example related to an RV or RV subset indicator is provided above.

QoS is another possible basis for determining the further transmission at 1108, and accordingly in some embodiments the traffic handling property based upon which the further transmission is determined is a quality of service associated with the LDPC coded bit sequence. For example, the SD RV subset {RV0, RV4, RV5, RV6} in FIG. 9 may be automatically selected and used for traffic associated with a service that has a low packet delay budget, and the NR RV subset {RV0, RV1, RV2, RV3} in FIG. 9 can be automatically selected and used for traffic associated with a service that has a high packet delay budget. In an example provided above, RV or RV subset selection is based on a 5QI threshold. This is one example of QoS-based determination of a further transmission. If the 5QI value of a service or traffic exceeds (or meets, in some embodiments) a threshold, then a UE (or network device) may select a further transmission (such as an RV or RV subset) with relatively higher self-decodability, and otherwise, if the 5QI value of a service or traffic is smaller than or below that threshold in this example, a UE (or network device) may select a further transmission with relatively lower self-decodability but higher IR combining gain.

The traffic handling property upon which determination of the further transmission is based may be or include a repetition configuration in some embodiments. According to a repetition configuration, repetition transmission is used, in which data is transmitted repeatedly several times in consecutive resources. A further transmission with higher self-decodability may be preferred for a repetition configuration. For example, a further transmission that has higher self-decodability may be determined, by automatically selection such a further transmission for example, if repetition transmission is configured. An example above refers to the field repK-RV. In an embodiment, a further transmission (such as an RV or an RV subset) with relatively higher self-decodability may be selected if the field repK-RV is configured in RRC, and otherwise a further transmission with relatively lower self-decodability but higher IR combining gain may be selected.

Grant-free scheduling is another example of a traffic handling property based upon which a further transmission may be determined. Grant-free scheduling enables UL data to be transmitted based on self-scheduling in a preconfigured resource. In an embodiment, if grant-free transmission is scheduled, then a further transmission may be determined by automatically selecting (by a UE for example) a further transmission (an RV or an RV subset such as the SD RV subset) that has relatively higher self-decodability. Otherwise, the IR RV subset, or more generally a further transmission (an RV or an RV subset) that has relatively lower self-decodability but higher IR combining gain, can be selected.

Regarding autonomous retransmission (in an unlicensed back for example) as a traffic handling property based upon which a further transmission is determined, the further transmission may be determined by the UE and indicated to a network device such as a BS. This may involve the UE transmitting (and the network device receiving) signaling that indicates the determined further transmission. The signaling may be in UCI, and the indication may be an RV index or other identifier of a further transmission, for example. In an example above, the UE may sense that the channel is available and then perform an autonomous transmission and subsequent retransmission if an initial transmission has failed, with the automatically selecting a further transmission that has higher self-decodability (the SD RV subset for example). Otherwise, for example if the initial transmission is not lost, then the IR RV subset, or more generally a further transmission (an RV or an RV subset for example) with relatively lower self-decodability but higher IR combining gain, may be selected.

Pre-emption is discussed above, by way of example with reference to FIG. 10, and is another possible traffic handling property based upon which a further transmission may be determined. Pre-emption refers to pre-emption of a portion of bits from an LDPC coded bit sequence for inclusion in the initial transmission. FIG. 10 illustrates pre-emption of eMBB for inclusion of URLLC.

In the case of pre-emption, at least part of an originally scheduled initial transmission has been punctured and replaced, and accordingly a further transmission with higher self-decodability may be preferred. In an embodiment, a further transmission is determined by automatically selecting the SD RV subset, or more generally a further transmission with high self-decodability, if there has been a pre-emption of part of the initial transmission, and otherwise selecting a further transmission with lower self-decodability but higher combining gain.

Some embodiments may involve transmitting an indication of a pre-emption. A PI in DCI is provided above as an example of such an indication, but embodiments are not in any way limited to this particular type of indication, or to a DL indication transmitted by network device and received by a UE. A pre-emption indication for a pre-emption that impacts a UL transmission may be transmitted by a UE and received by a network device.

Effective code rate of the initial transmission is another example of the traffic handling property based upon which the further transmission may be determined. A further transmission (an RV or an RV subset, for example) that has higher self-decodability may be preferred for lower code rates, and a further transmission that has lower self-decodability but higher combining gain may be preferred for higher code rates. In some embodiments, a further transmission is determined by selecting a further transmission that has higher self-decodability responsive to initial transmission effective CR below a threshold CR, and otherwise selecting a further transmission that has lower self-decodability but higher combining gain responsive to initial transmission effective CR at or above the threshold CR.

Some embodiments may involve receiving an indication of selection of the further transmission based on the traffic handling property. For example, a BS or other network device may configure, in RRC signaling for example, which RV subset to be used, or more generally one or more further transmissions that are to be used. At a receiver of such an indication, which is a UE in the case an indication in DCI for example, the further transmission that is to be used is then determined based on the received indication.

A transmitting device that has data to transmit may receive an indication of selection of a further transmission as described above, but may instead transmit such an indication. As an example, a network device that selects a further transmission (such as an RV or RV subset) that is to be used for a subsequent transmission may transmit an indication of the selection to an intended receiver of the initial transmission. Thus, some embodiments may involve determining a further transmission that is to be used (by making a selection of the further transmission from the number of further transmissions based on the traffic handling property, in this example), and transmitting an indication of the selection.

An example of such an indication is provided above, with 2 bits to indicate RV index within a subset of 4 RVs and 1 bit to indicate one of two RV subsets.

Embodiments consistent with the present disclosure may provide or support other features, and several examples are included in FIG. 11. Encoding of input bits to generate an LDPC coded bit sequence such as a mother codeword is shown at 1104. At least parts of such a coded bit sequence are also be transmitted, but encoding 1104 and the transmitting at 1106, 1108 may be performed separately. In some embodiments, a coded bit sequence is obtained or generated by encoding input bits 1104 by an LDPC code, and the resultant coded bit sequence may be output by an encoder for further processing or handling, including transmission in the example shown in FIG. 11. The coded bit sequence may be output to memory, for example, and accordingly the transmitting at 1106, 1108 may involve transmitting bits from a coded bit sequence that was previously generated or otherwise generated separately from the transmitting. A device or component that transmits an initial transmission and one or more further transmissions need not itself also encode input bits to generate a coded bit sequence.

Similarly, obtaining input bits for encoding, as shown at 102 in FIG. 11, may be performed or supported separately from encoding at 1104 and/or transmitting at 1106, 1108. The input bits for encoding may be or include data from different devices and/or data associated with different services, for example. Obtaining the input bits at 1102 may involve, for example, collecting or otherwise receiving data outputs from one or more devices and/or services, or accessing data in a memory.

Some embodiments may involve either or both of obtaining input bits at 1102 or generating a coded bit sequence by encoding the input bits at 1104. Bits from a coded bit sequence that is obtained or generated at 1104 may be transmitted at 1106, 1108 for example, or first output for storage to memory and then transmitted.

Thus, in some embodiments, a method may involve obtaining input bits as shown at 1102, encoding as shown at 1104, and transmitting as shown at 1106, 1108. Other embodiments may involve transmitting as shown at 1106, 1108, and the obtaining at 1102 and/or the encoding at 1104 may be performed separately.

Some embodiments may involve, from an encoder or transmitter perspective, receiving a retransmission request, which may be or include negative acknowledgement signaling or another form of retransmission request, and transmitting further bits in a further transmission at 1108 responsive to the request. In an embodiment, a method may involve receiving, by a first communication device from a second communication device for example, a request for retransmission after a decoding failure at 1154. There may be multiple cycles of retransmission requests and transmitting at 1108.

Another example of features that may be provided in some embodiments but are not explicitly shown in FIG. 11 relates to signaling. Some embodiments may involve transmitting and/or receiving signaling or any of various types of indications. More generally, embodiments may involve communicating, in a wireless communication network, signaling indicative of any of various parameters. Parameters related to one or both of encoding or decoding may also or instead be indicated in signaling.

Such communicating of signaling may involve transmitting the signaling by an encoder/encoding device or a transmitter/transmitting device that is to transmit codewords, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which encoded blocks are to be transmitted or received. For example, a network device such as a gNB or a base station may transmit signaling to configure parameters at one or more communication devices. Therefore, a method may involve a network device transmitting signaling, and an encoder/encoding device or a transmitter/transmitting device receiving the signaling from the network device, and/or a decoder/decoding device or a receiver/receiving device receiving the signaling from the network device.

At 1150, FIG. 11 illustrates various decoding and/or receiving counterparts of the features shown at 1100. From a receiving device perspective, the receiving at 1152 is intended to represent receiving encoded bits from an LDPC coded bit sequence. The encoded bits received at 1152 may be received in an initial transmission or a further transmission.

Although both an initial transmission and a further transmission may be transmitted at 1106, 1108, it is possible that the further transmission at 1108 is a result of the initial transmission at 1106 being lost, and not being received at 1152. Therefore, the receiving at 1152 may involve receiving a further transmission, and not necessarily receiving an initial transmission. The further transmission that includes further bits from an LDPC coded bit sequence, further to bits from the LDPC coded bit sequence that were included in the initial transmission. As in other embodiments, the further transmission would have been determined, based on a traffic handling property related to the coded bit sequence, from among a number of further transmissions that have associated self-decodability and combining gain properties.

Decoding is shown at 1154, and involves decoding (at least) the further transmission. The decoding at 1154 may or may not be successful. In the event of a decoding failure, a retransmission may be requested at 1156, and this may involve transmitting a retransmission request. A further transmission at 1108 in response to a retransmission request may be a first further transmission after an initial transmission (if the initial transmission is received but decoding fails, for example), or a subsequent further transmission if multiple further transmissions are supported. This cycle of 1152, 1154, 1156 may be repeated a number of times or until the decoding at 1154 is successful or a maximum number of further transmissions is reached, for example.

An initial transmission might be erased in a channel and not be received at all at 1154, in which case an RV may be transmitted at 1108 without an explicit retransmission request having been transmitted at 1156. Therefore, as also noted above, at 1152 a further transmission may be received without an initial transmission having been received.

A further transmission that is received at 1152 may be determined based on any of various traffic handling parameters. The following features may be provided or supported, individually or in any combination:
the traffic handling property may be a traffic priority associated with the LDPC coded bit sequence;
the traffic handling property may be a quality of service associated with the LDPC coded bit sequence;
the traffic handling property may be a repetition configuration;
the traffic handling property may be grant-free scheduling;
the traffic handling property may be autonomous retransmission;
the traffic handling property may be pre-emption of a portion of the bits from the LDPC coded bit sequence for inclusion in the initial transmission;
the traffic handling property comprises a code rate associated with the initial transmission.

In the case of pre-emption, a method may also involve receiving an indication of the pre-emption.

In some embodiments, there is a selection of the further transmission based on the traffic handling property, by another device, and method involves receiving (by a receiving device that receives the further transmission) an indication of the selection. In this scenario, the further transmission is determined by the receiving device based on the received indication.

In another embodiment, a method may involve transmitting (by the receiving that receives the further transmission) an indication of its own selection (by the receiving device) of the further transmission based on the traffic handling property. In the case of a UL transmission for example, a network device may be the receiving device, and may also be responsible for selection of the further transmission and configuring (or otherwise indicating) the selection to a transmitting device.

Other features not explicitly shown in FIG. 11 may be provided or supported, or may at least affect decoding-side or receiving-side operations. Features that are disclosed herein with reference to encoding or transmitting may have counterpart decoding or receiving features, for example.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor that is configured, by executing programming for example, to cause the apparatus to perform a method or operations, or to provide or support features, disclosed herein. An apparatus may also include a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to, or a processor, device, or other component may otherwise be configured to: transmit, in an initial transmission, bits from an LDPC coded bit sequence; and transmit, in a further transmission, further bits from the LDPC coded bit sequence. Programming stored in or on a non-transitory computer readable storage medium may also or instead include instructions to or to cause a processor to, or a processor, device, or other component may otherwise be configured to also or instead: receive and decode a further transmission that includes further bits from an LDPC coded bit sequence. In such embodiments, as in others, the further transmission would have been determined, based on a traffic handling property related to the coded bit sequence, from among a number of further transmissions that have associated self-decodability and combining gain properties.

Apparatus embodiments are not limited to the foregoing examples, or to processor-based or programming-based embodiments. An apparatus may include, for example, an encoder for encoding an input bit sequence by an LDPC code to obtain an LDPC coded bit sequence, and a transmitter or an interface, coupled to the encoder, for transmitting, in an initial transmission, bits from the LDPC coded bit sequence, and for transmitting, in a further transmission, further bits from the LDPC coded bit sequence, as disclosed herein.

An apparatus may also or instead include a receiver or an interface for receiving a further transmission that includes further bits from an LDPC coded bit sequence as disclosed herein, and a decoder coupled to the interface, for decoding the further transmission.

FIG. 12 is a block diagram illustrating an apparatus according to an embodiment. At 1200, FIG. 12 illustrates components of an example apparatus in which or in conjunction with which transmitting and/or encoding features may be implemented, and components of an example apparatus in which or in conjunction with which receiving and/or decoding features may be implemented is illustrated at 1250. A controller 1230 may be provided in either of these types of apparatus. In some embodiments, an apparatus may include both transmitting and receiving features, and either or both of encoding features or decoding features. In the example shown in FIG. 12, an apparatus with all of the illustrated components supports both encoding features and decoding features, as well and transmitting features and receiving features.

For encoding features and transmitting features, the example apparatus in FIG. 12 includes an input interface 1202, an encoder 1204 coupled to the input interface, an output interface shown by way of example as a transmitter 1206 coupled to the encoder, and a controller 1230 coupled to the encoder and the transmitter. An input bit sequence for encoding is shown as an input to the input interface 1202, and encoded bits are shown as outputs from the transmitter 1206. Although shown as a separate component in FIG. 12, the transmitter 1206 or another type of output interface for transmitting or otherwise outputting codewords may be provided by, incorporated into, or coupled to the encoder 1204. Similarly, although shown as a separate input interface 1202 in FIG. 12, an interface through which input bits for encoding are obtained by the encoder 1204 may be provided by, incorporated into, or coupled to the encoder.

Encode-side or transmit-side features or functions, and other features or functions herein, may be implemented in any of various ways, such as in hardware, firmware, or one or more components that execute software. The present disclosure is not limited to any specific type of implementation, and implementation details may vary between different devices.

Input bits may be obtained, and coded bit sequences may be transmitted or otherwise output, via any of various types of interface, including a communication interface in the case of transmitting coded bit sequences or receiving input bits for encoding. Embodiments are not in any way restricted to any particular type of interface, the implementation of which may be based at least in part on how input bits are to be obtained and how coded bit sequences are to be output.

In an embodiment, an apparatus includes an encoder such as the encoder 1204 for encoding an input bit sequence by an LDPC code to obtain an LDPC coded bit sequence. An interface may be provided and coupled to an encoder, and in the example shown the transmitter 1206 is coupled to the encoder 1204 for transmitting bits from the LDPC coded bit sequence. In particular, the transmitter 1206 in this example, or more generally an interface coupled to the encoder 1204, is for transmitting, in an initial transmission, bits from the LDPC coded bit sequence, and for transmitting, in a further transmission, further bits from the LDPC coded bit sequence. As in other embodiments, the further transmission would have been determined, based on a traffic handling property related to the coded bit sequence, from among a number of further transmissions that have associated self-decodability and combining gain properties.

An apparatus may also include an interface such as the interface 1202 in some embodiments, for receiving input bits for encoding by the encoder 1204.

More generally, an apparatus or a component thereof such as an encoder 1204 or a processor may be configured to encode (or for encoding) an input bit sequence, or programming may include instructions to encode (or for encoding) an input bit sequence or to cause a processor to encode an input bit sequence, by an LDPC code to obtain or generate an LDPC coded bit sequence. An apparatus or a component thereof such as a transmitter 1206 or more generally an interface, which may be coupled to the encoder 1204, may be configured to transmit (or for transmitting) or to otherwise output (or for outputting), or programming may include instructions to transmit (or for transmitting) or to otherwise output (or for outputting) or to cause a processor to transmit or otherwise output, bits as disclosed herein. Outputting may involve outputting the bits for an initial transmission and one or more further transmissions, or transmitting the bits in an initial transmission and one or more further transmissions, for example.

Embodiments related to such apparatus or non-transitory computer readable storage media may include any one or more of the following features, for example, which are also discussed elsewhere herein:
the traffic handling property may be a traffic priority associated with the LDPC coded bit sequence;
the traffic handling property may be a quality of service associated with the LDPC coded bit sequence;
the traffic handling property may be a repetition configuration;
the traffic handling property may be grant-free scheduling;
the traffic handling property may be autonomous retransmission;
the traffic handling property may be pre-emption of a portion of the bits from the LDPC coded bit sequence for inclusion in the initial transmission;
the apparatus or a component thereof such as an encoder 1204, a transmitter 1206, or an interface may be configured to transmit (or for transmitting), or programming may include instructions to transmit (or for transmitting), or to cause a processor to transmit an indication of the pre-emption;
the traffic handling property may be a code rate associated with the initial transmission;
the apparatus or a component thereof such as an encoder 1204 or a receiver 1256 may be configured to receive (or for receiving), or programming may include instructions to receive (or for receiving), or to cause a processor to receive an indication of selection of the further transmission from the number of further transmissions based on the traffic handling property, in which case the further transmission is determined based on the indication;
the apparatus or a component thereof such as an encoder 1204, a transmitter 1206, or an interface may be configured to transmit (or for transmitting), or programming may include instructions to transmit (or for transmitting), or to cause a processor to transmit an indication of selection of the further transmission from the number of further transmissions based on the traffic handling property.

With reference again to FIG. 12, the example apparatus also includes components to provide or support receiving and decoding features. These components may be provided separately in a decoding or receiving device, or together with other components to provide or support decoding or receiving features together with encoding or transmitting features.

An input interface, shown in the form of a receiver 1256, is coupled to a decoder 1254, and these components are also coupled to the controller 1230. The decoder 1254 is coupled to an output interface 1252. A recovered bit sequence is shown as an output from the output interface 1252, and encoded bits are shown as inputs received by the receiver 1256. The receiver 1256 or another type of interface for receiving or otherwise obtaining encoded bits for decoding may be provided by, incorporated into, or coupled to the decoder 1254, and similarly an interface through which a recovered bit sequence is output by the decoder may be provided by, incorporated into, or coupled to the decoder.

Decode-side or receive-side features or functions, and other features or functions herein, may be implemented in any of various ways, such as in hardware, firmware, or one or more components that execute software. The present disclosure is not limited to any specific type of implementation, and implementation details may vary between different devices, for example.

Encoded bits may be received or otherwise obtained, and a recovered bit sequence may be output, via any of various types of interface, including the receiver 1256 or another type of communication interface in the case of receiving encoded bits or transmitting a recovered bit sequence. Embodiments are not in any way restricted to any particular type of receiver or interface, the implementation of which may be based at least in part on how encoded bits for decoding are to be obtained and how a recovered bit sequence is to be output. Encoder and decoder interfaces are shown separately in FIG. 12 to illustrate that encoding and decoding features may be implemented independently. However, it should be appreciated that a single device or equipment may support both encoding and decoding, in which case an encoder and a decoder may be coupled to the same interface(s) at 1202, 1252. For example, the encoder 1204 and the decoder 1254 may be coupled to the same interface(s) to obtain a bit sequence for encoding by the encoder and to output bit sequences recovered by the decoder. The encoder 1204 and the decoder 1254 may also or instead be coupled to the same interface(s) to output coded bit sequences that are generated by the encoder and receive encoded bits for decoding by the decoder.

In an embodiment, an apparatus includes a decoder such as the decoder 1254 for decoding received transmissions, including at least a further transmission as disclosed herein. The receiver 1256 or another interface may be provided, and coupled to a decoder in some embodiments, for receiving at least a further transmission as disclosed herein. An apparatus may also include an interface such as the output interface 1252 in some embodiments, for outputting recovered bit sequences. More generally, an apparatus or a component thereof such as a decoder 1254 or a processor may be configured to decode (or for decoding) a further transmission to recover a bit sequence, or programming may include instructions to decode (or for decoding) a further transmission to recover a bit sequence or to cause a processor to decode a further transmission to recover a bit sequence. An apparatus or a component thereof such as a receiver 1256 or an interface coupled to the decoder 1254, may be configured to receive (or for receiving) or to otherwise obtain (or for obtaining), or programming may include instructions to receive (or for receiving) or to otherwise obtain (or for obtaining) or to cause a processor to receive or otherwise obtain, the further transmission. Receiving may involve receiving the further transmission from a first communication device by a second communication device in a wireless communication network for example.

As in other embodiments, the further transmission includes further bits from an LDPC coded bit sequence, and the further bits are further to bits from the LDPC coded bit sequence that are included in an initial transmission. The further transmission would have been determined, based on a traffic handling property related to the coded bit sequence, from among a number of further transmissions that have associated self-decodability and combining gain properties.

Embodiments related to such apparatus or non-transitory computer readable storage media may include any one or more of the following features, for example, which are also discussed elsewhere herein:
the traffic handling property may be a traffic priority associated with the LDPC coded bit sequence;
the traffic handling property may be a quality of service associated with the LDPC coded bit sequence;
the traffic handling property may be a repetition configuration;
the traffic handling property may be grant-free scheduling;
the traffic handling property may be autonomous retransmission;
the traffic handling property may be pre-emption of a portion of the bits from the LDPC coded bit sequence for inclusion in the initial transmission;
the apparatus or a component thereof such as a decoder 1254 or a receiver 1256 may be configured to receive (or for receiving), or programming may include instructions to receive (or for receiving), or to cause a processor to receive an indication of the pre-emption;
the traffic handling property may be a code rate associated with the initial transmission;
the apparatus or a component thereof such as a decoder 1254 or a receiver 1256 may be configured to receive (or for receiving), or programming may include instructions to receive (or for receiving), or to cause a processor to receive an indication of selection of the further transmission from the number of further transmissions based on the traffic handling property, in which case the further transmission is determined based on the indication;
   the apparatus or a component thereof such as a decoder 1254, a transmitter 1206, or an interface may be configured to transmit (or for transmitting), or programming may include instructions to transmit (or for transmitting), or to cause a processor to transmit an indication of selection of the further transmission from the number of further transmissions based on the traffic handling property.

Other features disclosed herein may also or instead be provided or supported in apparatus embodiments.

Apparatus embodiments are not in any way restricted to single devices. A system, for example, may include a first communication device and a second communication device. The first communication device may be configured to encode an input bit sequence by an LDPC code to obtain an LDPC coded bit sequence; to transmit, in an initial transmission, bits from the LDPC coded bit sequence; and to transmit, in a further transmission, further bits from the LDPC coded bit sequence. The second communication device may be configured to receive the further transmission, and to decode the further transmission. The further transmission would have been determined, based on a traffic handling property related to the coded bit sequence, from among a number of further transmissions that have associated self-decodability and combining gain properties.

More generally, other features disclosed herein may also or instead be provided in method, apparatus, and/or system embodiments.

Example embodiments disclosed herein may include the following benefits or features:
A new RV set which has more RVs than current NR RV:
   Additional RVs having a good combination of IR combining gain and self-decodability may be included in the current NR RV set;
   Completely new RV designs where some RVs have high self-decodability and low IR combining gain and vice versa.
From this big RV set, 2 subsets of RVs with different attributes can be generated:
   IR RV subset: Low self-decodability yet high IR combining gain at some RVs;
high self-decodability yet very low IR gain at other RVs
   SD RV subset: Good combination of IR combining gain and self-decodability (high self-decodability at all RVs, better IR gain than some RVs in IR RV set). Given above 2 RV subsets, methods of RV configuration include:
   Methods to automatically select the RV subset by a UE with no extra overhead in DCI, based on: traffic priority, QoS, repetition configuration, grant-free, autonomous retransmission in unlicensed band, BS configuration, pre-emption indication, effective code rate of initial transmission;
   Methods to select RV set with 1 extra bit in “Redundancy version” parameter (now total 3 bits) in DCI-3^{rd} (last) bit can be used to indicate the RV subset, or use 3 bits to map to the RV index of the big RV set.
Two RV subsets with different attributes can be used in different scenarios (for example, different traffics (eMBB or URLLC), pre-emptive eMBB retransmission, or different CR), in order to improve performance.
No extra overhead in control signaling.
Backward compatibility: For a UE with only 5G capability, the transmission can be based on the NR RV set alone by default.

These are examples only, any one or more of which may be provided in at least some embodiments. In the last item “Backward compatibility,” transmission based on the NR RV may encompass a sequence or series of transmissions (initial and further transmissions) rather than only a single transmission.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

For example, features disclosed herein with reference to an initial transmission and a further transmission may also or instead apply to different further transmissions. For example, with reference to FIGS. 5 and 8, RV1, RV2, and RV3 are not initial transmissions, but each includes further LDPC coded bits that are not included in the other. The same applies between RV4, RV6, and RV6 in FIG. 7.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Aspects of the present invention have been described with reference to specific features and embodiments thereof. Various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

What is claimed is:

1. A method comprising:
transmitting, in an initial transmission, bits from a low density parity check (LDPC) coded bit sequence; and
transmitting, in a further transmission, further bits from the LDPC coded bit sequence,
the further transmission having been determined, based on a traffic handling property related to the LDPC coded bit sequence, from among a plurality of further transmissions that have associated self-decodability and combining gain properties.

2. The method of claim 1, wherein the traffic handling property comprises at least one of:
a traffic priority associated with the LDPC coded bit sequence,
a quality of service associated with the LDPC coded bit sequence,
a repetition configuration,
grant-free scheduling,
autonomous retransmission,
pre-emption of a portion of the bits from the LDPC coded bit sequence for inclusion in the initial transmission, or
a code rate associated with the initial transmission.

3. The method of claim 2, wherein:
the traffic handling property comprises the pre-emption of the portion of the bits from the LDPC coded bit sequence for inclusion in the initial transmission, and
the method further comprises:
transmitting an indication of the pre-emption.

4. The method of claim 1, further comprising:
receiving an indication of selection of the further transmission from among the plurality of further transmissions based on the traffic handling property,
wherein the further transmission is determined based on the indication.

5. The method of claim 1, further comprising:
transmitting an indication of selection of the further transmission from among the plurality of further transmissions based on the traffic handling property.

6. A method comprising:
receiving a further transmission that includes further bits from a low density parity check (LDPC) coded bit sequence, the further bits being in addition to bits from the LDPC coded bit sequence included in an initial transmission,
the further transmission having been determined, based on a traffic handling property related to the LDPC coded bit sequence, from among a plurality of further transmissions that have associated self-decodability and combining gain properties; and
decoding the further transmission.

7. The method of claim 6, wherein the traffic handling property comprises at least one of:
a traffic priority associated with the LDPC coded bit sequence,
a quality of service associated with the LDPC coded bit sequence,
a repetition configuration,
grant-free scheduling,
autonomous retransmission,
pre-emption of a portion of the bits from the LDPC coded bit sequence for inclusion in the initial transmission, or
a code rate associated with the initial transmission.

8. The method of claim 7, wherein:
the traffic handling property comprises the pre-emption of the portion of the bits from the LDPC coded bit sequence for inclusion in the initial transmission, and
the method further comprises:
receiving an indication of the pre-emption.

9. The method of claim 6, further comprising:
receiving an indication of selection of the further transmission from among the plurality of further transmissions based on the traffic handling property,
wherein the further transmission is determined based on the indication.

10. The method of claim 6, further comprising:
transmitting an indication of selection of the further transmission from among the plurality of further transmissions based on the traffic handling property.

11. An apparatus comprising:
at least one processor; and
a memory coupled to the at least one processor, the memory for storing instructions that, when executed by the at least one processor, cause the apparatus to:
transmit, in an initial transmission, bits from a low density parity check (LDPC) coded bit sequence; and
transmit, in a further transmission, further bits from the LDPC coded bit sequence,
the further transmission having been determined, based on a traffic handling property related to the LDPC coded bit sequence, from among a plurality of further transmissions that have associated self-decodability and combining gain properties.

12. The apparatus of claim 11, wherein the traffic handling property comprises at least one of:
a traffic priority associated with the LDPC coded bit sequence,
a quality of service associated with the LDPC coded bit sequence,
a repetition configuration,
grant-free scheduling,
autonomous retransmission,
pre-emption of a portion of the bits from the LDPC coded bit sequence for inclusion in the initial transmission, or
a code rate associated with the initial transmission.

13. The apparatus of claim 12, wherein:
the traffic handling property comprises the pre-emption of the portion of the bits from the LDPC coded bit sequence for inclusion in the initial transmission, and
the instructions further cause the apparatus to:
transmit an indication of the pre-emption.

14. The apparatus of claim 11, wherein the instructions further cause the apparatus to:
receive an indication of selection of the further transmission from among the plurality of further transmissions based on the traffic handling property,
wherein the further transmission is determined based on the indication.

15. The apparatus of claim 11, wherein the instructions further cause the apparatus to:
transmit an indication of selection of the further transmission from among the plurality of further transmissions based on the traffic handling property.

16. An apparatus comprising:
at least one processor; and
a memory coupled to the at least one processor, the memory for storing instructions that, when executed by the at least one processor, cause the apparatus to:
receive a further transmission that includes further bits from a low density parity check (LDPC) coded bit sequence, further bits beings in addition to bits from the LDPC coded bit sequence included in an initial transmission,
the further transmission having been determined, based on a traffic handling property related to the LDPC coded bit sequence, from among a plurality of further transmissions that have associated self-decodability and combining gain properties; and
decode the further transmission.

17. The apparatus of claim 16, wherein the traffic handling property comprises at least one of:
a traffic priority associated with the LDPC coded bit sequence,
a quality of service associated with the LDPC coded bit sequence,
a repetition configuration,
grant-free scheduling,
autonomous retransmission,
pre-emption of a portion of the bits from the LDPC coded bit sequence for inclusion in the initial transmission, or
a code rate associated with the initial transmission.

18. The apparatus of claim 17, wherein:
the traffic handling property comprises the pre-emption of the portion of the bits from the LDPC coded bit sequence for inclusion in the initial transmission, and
the instructions further cause the apparatus to:
receive an indication of the pre-emption.

19. The apparatus of claim 16, wherein the instructions further cause the apparatus to:
receive an indication of selection of the further transmission from among the plurality of further transmissions based on the traffic handling property,
wherein the further transmission is determined based on the indication.

20. The apparatus of claim 16, wherein the instructions further cause the apparatus to:
transmit an indication of selection of the further transmission from among the plurality of further transmissions based on the traffic handling property.
